(19) United States
(12) Patent Application Publication
(10) Pub. No.: US 2011/0031596 A1
(43) Pub. Date: Feb. 10, 2011

(54) NICKEL-TITANUM SOLDERING LAYERS IN SEMICONDUCTOR DEVICES

(76) Inventors: Mike D. Gruenhagen, Salt Lake City, UT (US); James J. Murphy, South Jordan, UT (US); Suku Kim, South Jordan (KR); Jim Pierce, Sandy, UT (US); William S. Beggs, Salt Lake City, UT (US); Thomas P. Welch, South Jordan, UT (US)

Correspondence Address: KENNETH E. HORTON;KIRTON & MCCONKLE, 60 EAST SOUTH TEMPLE, SUITE 1800, SALTLAKE CITY, UT, 84111, US

(21) Appl. No.: 12/535,963

(22) Filed: Aug. 5, 2009

(51) Int. Cl. H01L 23/495; H01L 23/498; H01L 23/488; B23K 35/22

(52) U.S. Cl. 257/666; 257/737; 257/690; 428/576; 257/E23.031; 257/E23.068; 257/E23.023

(57) ABSTRACT

Semiconductor devices containing nickel-titanium (NiTi or TiNi) compounds or alloys and methods for making such devices are described. The devices contain a silicon substrate with an integrated circuit, a contact layer contacting the substrate, a TiNi-containing soldering layer on the contact layer, an oxidation prevention layer on the soldering layer, a solder bump on the soldering layer, and a lead frame or PCB attached to the solder bump. The combination of the Ti and Ni materials in the soldering layer exhibits many features not found in the Ti and Ni materials alone, such as reduced wafer warpage, increased ductility for improved elasticity, decreased consumption of the Ni in the soldering layer, and decreased manufacturing costs. Other embodiments are described.

### FIELD

This application relates generally to semiconductor devices and methods for making such devices. More specifically, this application relates to nickel-titanium (NiTi or TiNi) alloys that can be used for soldering layers underlying solders in semiconductor devices.

### BACKGROUND

Semiconductor devices containing integrated circuits (ICs) are used in a wide variety of electronic apparatus. The IC devices (or chips) comprise a miniaturized electronic circuit that has been manufactured in the surface of a substrate of semiconductor material. The circuits are composed of many overlapping layers, including layers containing dopants that can be diffused into the substrate (called diffusion layers) or ions that are implanted (implant layers) into the substrate. Other layers are conductors (polysilicon or metal layers) or connections between the conducting layers (via or contact layers).

IC devices can be fabricated in a layer-by-layer process that uses a combination of many steps, including imaging, deposition, etching, doping and cleaning. Silicon wafers are typically used as the substrate and photolithography is used to mark different areas of the substrate to be doped or to deposit and define polysilicon, insulators, or metal layers. One of the latter steps in the semiconductor fabrication process forms the electrical connections between the circuitry and the other electrical components in the electronic apparatus of which the IC chip is a part. While older technology utilized wire bonding, newer technology includes flip chip bonding processes where the active side of the IC chip is bonded to an electrical circuit of the printed circuit board (PCB) through solder bumps deposited either on the IC chip or the PCB. Some of the flip chip bonding processes can be used to make wafer level chip scale packages (WLCSP).

### SUMMARY

This application relates to semiconductor devices containing nickel-titanium (NiTi or TiNi) compounds or alloys and methods for making such devices. The devices contain a silicon substrate with an integrated circuit, a contact layer contacting the substrate, a TiNi-containing soldering layer on the contact layer, an oxidation prevention layer on the soldering layer, a solder bump on the soldering layer, and a lead frame or PCB attached to a layer of solder or a solder bump. The combination of the Ti and Ni materials in the soldering layer exhibits many features not found in the Ti and Ni materials alone, such as reduced wafer warpage, increased ductility for improved elasticity, decreased consumption of the Ni in the soldering layer, improved protection against environmental exposures, and decreased manufacturing costs.

### BRIEF DESCRIPTION OF THE DRAWINGS

The following description can be better understood in light of the Figures, in which:

FIG. 1 shows some embodiments of methods for forming a semiconductor device containing a contact layer and a TiNi soldering layer;

FIG. 2 depicts some embodiments of methods for forming a semiconductor device containing a TiNi soldering layer, an oxidation prevention layer, solder paste, and a solder ball;

FIG. 3 shows some embodiments of methods for forming a semiconductor device containing a TiNi soldering layer with front and backside lead frames; and

FIG. 4 depicts some embodiments of methods for forming a semiconductor device containing a TiNi soldering layer used in a WLCSP.

The Figures illustrate specific aspects of the semiconductor devices and methods for making such devices. Together with the following description, the Figures demonstrate and explain the principles of the methods and structures produced through these methods. In the drawings, the thickness of layers and regions are exaggerated for clarity. It will also be understood that when a layer, component, or substrate is referred to as being “on” another layer, component, or substrate, it can be directly on the other layer, component, or substrate, or intervening layers may also be present. The same reference numerals in different drawings represent the same element, and thus their descriptions will not be repeated.

### DETAILED DESCRIPTION

The following description supplies specific details in order to provide a thorough understanding. Nevertheless, the skilled artisan would understand that the devices and associated methods of making and using the devices can be implemented and used without employing these specific details. Indeed, the devices and associated methods can be placed into practice by modifying the illustrated devices and associated methods and can be used in conjunction with any other apparatus and techniques conventionally used in the industry. For example, while the description below focuses on methods for making for semiconductor devices in the IC industry, it could be used in and applied to other electronic devices like optoelectronic devices, solar cells, MEMS structures, lighting controls, power supplies, and amplifiers.

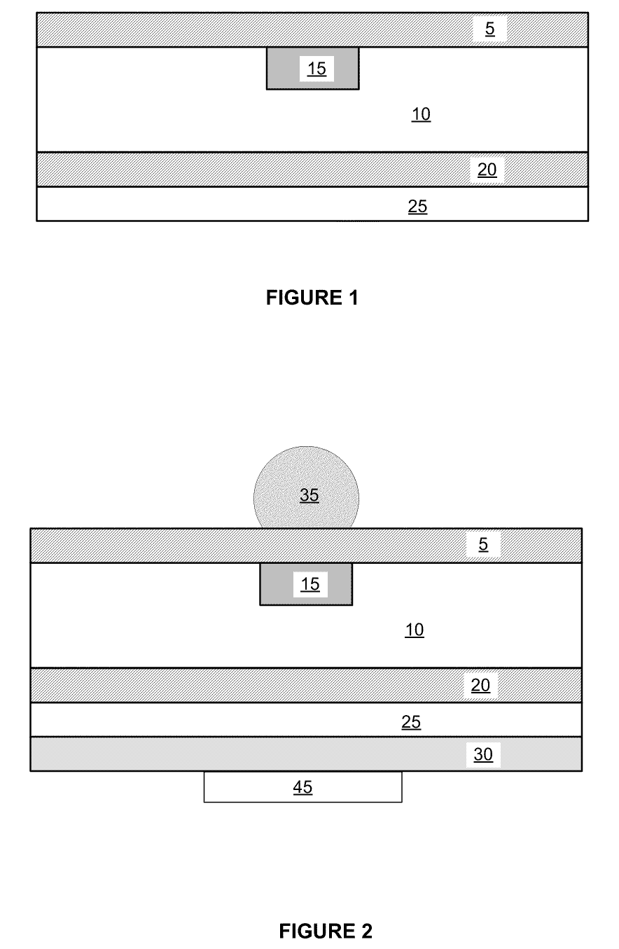

Some embodiments of the semiconductor devices and methods for making such devices are shown in FIGS. 1-3. In these embodiments, the methods for making the semiconductor devices begin by providing a substrate 10, as shown in FIG. 1. The substrate 10 may be made of any known semiconductor material. Some non-limiting examples of such materials may include silicon, gallium arsenide, silicon carbide, gallium nitride, silicon and germanium, and combinations thereof. In some embodiments, the substrate 10 comprises a silicon wafer with an epitaxial layer of Si deposited thereon. The silicon wafer and/or the epitaxial layer can be undoped or doped with any known dopant, including boron (B), phosphorous (P), and arsenic (As).

Next, as known in the art, any known integrated circuit (IC) 15 can be formed in or on the substrate 10 using any known processing. Some non-limiting examples of these IC devices may include logic or digital IC devices, linear regulators, audio power amplifiers, LDO, driver IC, diodes, and/or transistors, including zener diodes, schottky diodes, small signal diodes, bipolar junction transistors (“BJT”), metal-oxide-semiconductor field-effect transistors (“MOSFET”), insulated-gate-bipolar transistors (“IGBT”), and insulated-gate field-effect transistors (“IGFET”). In some embodiments, the IC device 15 comprises a trench MOSFET device that can be made using any process known in the art. In other embodiments, the IC device 15 comprises a double-diffused metal-oxide-semiconductor (DMOS) device. In yet other embodiments, the IC device 15 comprises any device containing a backside drain contact.

In some embodiments, a gate layer 5 has been formed on the upper surface of the substrate 10. The gate layer 5 is connected to the IC device 15 and serves as a gate for the IC device. In these embodiments, the gate layer 5 can be made of any conductive material such as Al, polysilicon, silicon/nickel silicide, or silicon/cobalt silicide and can be made by any process known in the art. In some instances, further processing, such as forming an interconnect (not shown) or forming a gate pad (not shown), can be performed on the upper surface of the gate layer 5 as known in the art. These steps on the front side of the wafer are used as part of the processing to manufacture the completed semiconductor device.

Next, the backside of the substrate 10 is thinned using any known process in the art. The backside of the substrate 10 can be thinned using any known polishing or grinding process. In some embodiments, the backside is thinned by providing a tape on the front side of the substrate 10 to operate as a support and surface protection, grinding the backside by using a diamond abrasive wheel, removing the grinding tape from the front side, and then performing a Stress Relief Etch (SRE) process using a wafer backside etching tool, such as those made by the SEZ Group or Materials and Technologies Corporation (MaTech). In some embodiments, the substrate 10 can be thinned to a thickness from about 400 to about 10 μm. In other embodiments, the substrate 10 can be thinned to a thickness just below the active gate transistor structure of the dopant activated source, channel and drain regions.

Then, a contact layer 20 can be formed on the backside of the substrate 10 as shown in FIG. 1 so that it is adjacent the drain of the IC device 15. The contact layer 20 operates as silicon-to-metal interface and/or adhesion layer between the substrate 10 and the to-be-formed soldering metal layer (as described herein). In some embodiments, the contact layer 20 comprises Ti or a Ti alloy such as Ti/Ni alloy. The materials can be formed by a chemical vapor deposition (CVD) process or by a metal co-evaporation process. In other embodiments, a physical vapor deposition (PVD) or sputtering process using either a NiTi target or two targets (a Ti target and a Ni target co-sputter) can be performed until the desired thickness of the TiNi alloy layer is formed.

Next, a soldering layer 25 can be formed on the contact layer 20. The soldering layer 25 operates to chemically react with the die attach Sn-containing solder to form a connection between the die and the leadframe of the semiconductor package. In some embodiments, the soldering layer 25 can operate as a diffusion barrier layer against ingression of oxidation prevention layer metals, such as gold or silver into the active silicon since is these metals diffused into the silicon, the device performance would degrade. The soldering layer 25 can comprise any metal that forms a metal Sn intermetallic layer under soldering conditions typically used to attach the die to a leadframe or solder Sn-containing spheres to a metal pad. Accordingly, in some embodiments, the soldering layer 25 can comprise TiNi compounds or alloys.

The soldering layer 25 can be formed by a chemical vapor deposition (CVD) process or by a metal co-evaporation process. In some embodiments, a physical vapor deposition (PVD) or sputtering process using either a NiTi target or two targets (a Ti target and a Ni target, co-sputter) can be performed until the desired thickness of the TiNi alloy layer is formed. As much as feasible, oxygen is not contained in the atmosphere during deposition because oxygen reacts with the soldering layer and prevents later reaction with the Sn in the solder. This reaction is also why the soldering layer 25 in some configurations can be followed by the deposition of an oxidation prevention layer without exposure to the atmosphere. The soldering layer 25 deposition process can continue until a thickness of about 0.1 to about 5 μm is obtained. In some embodiments, the thickness of the soldering layer 25 can range from about 0.2 to about 0.5 μm.

The amount of Ni in the TiNi material of the soldering layer 25 can be any amount that provides the physical characteristics described herein. In some embodiments, the amount of Ni in the TiNi alloy can range from about 0.5 to about 95.5 wt %. In other embodiments, the amount of Ni in the TiNi alloy can range from about 40 to about 60 wt % (narrow). In still other embodiments, the TiNi layer comprises Nitinol which can contain approximately 50 to about 55.6 wt % Ni. In even other embodiments, the TiNi layer contains approximately 51 wt % Ni (Ti₄₉Ni₅₁). The Ti₄₉Ni₅₁ formulation has a Young's Modulus of elasticity ranging from about 28 to about 75 GPA which can provide the ability to substantially absorb changes that can be induced during thermal expansion and contraction. When it is used, the temperature of the semiconductor device increases and the metal layers expand more than the silicon in the substrate. Conversely, when the device is turned off, the device cools and the metal layers and the silicon contract at different rates. This mismatch in the thermal expansion and contraction rate needs to be absorbed by an elastic material that is placed between the metal and silicon or cracks can develop in the interface between the silicon and the metal connection. Historically, elastic materials like solders have been used to help with this problem. Thus, the use of Ti/Ni alloys can also provide extra elastic strength to help hold the interconnection of the silicon and the metal together.

This ductile property is a feature that TiNi provides that neither Ti nor Ni exhibit. Ti and Ni metals by themselves are not very ductile materials since the Young's Modulus of elasticity for Ti is about 116 GPA and for Ni is about 200 GPA. Thus, Ti and Ni metals exhibit hard brittle properties. The result is that either metal is susceptible to cracking under fatique and stress conditions while the TiNi alloy will absorb the stress better and hold together.

The combination of the Ti and Ni materials in the soldering layer 25 exhibits many features that are not found in the Ti and Ni materials alone. Conventional soldering layers typically contained Ti or Ni, but not both. Soldering layers containing just Ti experienced problems during soldering process because of its extreme sensitivity to any oxygen in the soldering atmosphere. While it is possible to eliminate or reduce the amount of oxygen in the soldering atmosphere, it can be quite expensive. But by incorporating Ni into the soldering layer 25, the device can be less sensitive to small amounts (ppm levels) of oxygen.

Another problem with soldering layers containing layers of only Ti or Ni is the lack of corrosion resistance of the Ni layer. It is known that Ni layers can continue to corrode while Ti layers exhibit the ability to self-passivate as a TiO₂ material. An improved corrosion resistance is becoming more important because it can reduce or prevent corrosion-induced degradation, especially since semiconductor devices are increasingly being made without plastic mold encapsulation (i.e., wafer level chip scale packages [WLCSP]). But by combining the two metals into one alloy, it becomes possible to make a surface-rich passivating TiO₂ outer surface over the Ti/Ni alloy, thereby providing a passivation layer for environmental protection.

At the same time, soldering layers only containing Ni have also experienced problems. Soldering layers containing just Ni exhibit a high consumption rate during soldering when they are located adjacent Pb-free SAC solders. Solders typically contain metals like tin and lead and the soldering layer is used to prevent these metals from diffusing into the contact layer 20 and possibly even down to the substrate 10. Some solders have been formed of a eutectic lead-tin (PbSn) alloy that have 63 wt % tin and 37 wt % lead since it has a low melting temperature, which allows the solder to be reflowed at low temperatures of 210-220° C. But because of the detrimental environmental impact of lead, efforts have been recently expended in developing and using lead-free solders.

One type of lead-free solder that has been developed and used is a SAC solder. A SAC solder comprises an alloy of tin, silver, and copper. Typical formulations of SAC solders contain 3 to 4 wt % silver, 0.5 to 1.0 wt % copper, with the balance being tin. But SAC solders are known to react with, and thereby consume, the Ni in the soldering layer at a very high rate during the soldering process. But the Ti in the soldering layer reacts with the Sn in the solder at a much slower rate.

The Ni consumption by the SAC solder can result in cracks, intermetallic compound (IMC) spalling, and under-bump-metal (UBM) delamination. The cracks in the soldering layer are caused by the relatively low ductility of Ni and can result in brittle fractures across the solder joint. The IMC spalling can be caused by the IMC grains detaching themselves from the soldering layer/solder interface during reflow processing. This detachment causes this interface to be brittle due to voids or cracks that can be introduced into the SAC solder/Ni interface when the IMC grains grow larger. Thus, the UBM to solder delamination results in the layers underlying the soldering layer peeling away from each other, causing a broken interconnect and reliability degradation.

Some attempts to reduce this problem of Ni consumption have included increasing the size of the Ni soldering layer. The result of adding thickness to the Ni layer, is the additional amount of Ni added remains non-consumed after the soldering process. But the additional Ni thickness not only increases the size and cost of the completed device, but can also increase warpage of the underlying substrate 10. Ni has the potential to warp the underlying Si substrate, thereby preventing easy manufacturing and causing performance degradation. And increasing the thickness of the Ni layer only increases the potential to warp the wafer and can even cause wafer breakage. Other attempts to reduce the problem of Ni consumption have included incorporating Si into the Ni soldering layer.

As well, pure Ni compounds are brittle and can lead to fractures in the Ni soldering layer. NiTi materials, on the other hand, and especially Ti₄₉Ni₅₁ are very ductile relative to Ni compounds. The modulus of elasticity and Young's modulus of TiNi provides an improved elasticity, allowing it to withstand the stresses that are often put on solder joints, and decreasing both crack formation and also the failure rate. This ductile property is a feature that TiNi provides that neither Ti nor Ni alone exhibit. Ti and Ni metals by themselves are not very ductile materials since the Young's Modulus of elasticity for Ti is about 116 GPA and for Ni is about 200 GPA. Thus, Ti and Ni metals exhibit hard brittle properties. The result is that either metal is susceptible to cracking under fatique and stress conditions while the TiNi alloy will absorb the stress better and hold together.

The TiNi material in the soldering layer 25 can be formed by any process known in the art. In some embodiments, the materials can be formed by a chemical vapor deposition (CVD) process or by a metal co-evaporation process. In other embodiments, a physical vapor deposition (PVD) or sputtering process using either a NiTi target or two targets (a Ti target and a Ni target) can be performed until the desired thickness of the TiNi alloy layer is formed. The thickness of the TiNi soldering layer 25 can range from about 0.1 to about 5 μm. In some instances, the thickness of the TiNi-containing soldering layer can range from about 0.2 to about 0.5 μm.

Next, as shown in FIG. 2, an oxidation prevention (which in some embodiments could include an oxidation reducing) layer 30 can be formed on the soldering layer 25. The oxidation prevention layer 30 is formed to prevent the soldering layer 25 from being oxidized during later processing, including the soldering process. This oxygen prevention layer 30 can contain any material that will reduce or prevent oxidation of the material used in the soldering layer 25. In some embodiments, the oxidation prevention layer 30 comprises Ag, Au, Pd, Cu, or combinations thereof. The oxidation prevention layer 30 can be formed using any deposition process, including CVD or sputter deposition, until a thickness of about 0.01 to about 0.05 μm is obtained. In some embodiments, the oxidation prevention layer 30 can be deposited in an atmosphere containing negligible or no amounts of oxygen, such as an atmosphere containing Ar, He, Ne, inert gases, or combinations thereof.

In the embodiments where the front side of the wafer is provided with a lead frame, the TiNi soldering layer can also be formed on the front side of the substrate 10. In these embodiments, a contact layer 65 (similar to contact layer 20) is formed on the gate and source metal 5. Then, a TiNi soldering layer 70 (similar to soldering layer 25) is formed on the contact layer. And then, an oxidation prevention layer 75 (similar to oxidation layer 30) can be formed on the TiNi solder layer.

Next, the substrate 10 (which is often in the form of a wafer) can be separated into individual dies by any known dicing process. Then, the individual dies are attached to a lead frame using any process known in the art. In some embodiments, the dies can be attached to the lead frame using a soldering process. In the soldering process, and as shown in FIG. 2, solder balls 35 are deposited on the oxidation prevention layer 30 on the front side by using any known process, including electroplating, printing through a mask, solder paste dot dispense or a ball drop process. Where a leadframe is connected to the back side of the wafer, a solder paste material 45 is also deposited on the oxidation prevention layer 75 on the back side using any known process, including solder paste dispense, die attach and reflow.

The solder balls 35 and the solder paste 45 can be formed from any known solder material. In some embodiments, the solder balls 35 and the solder paste 45 can be formed with a die-attach solder such as eutectic Pb/Sn, high Pb/Sn or SnSb alloys, or a SAC solder. An SAC solder is an alloy of tin, silver, and copper. Typical formulations of SAC solders contain 3 to 4 wt % silver, 0.5 to 1.0 wt % copper, with the balance being tin. One formulation that can be used is SAC305, which contains 3 wt % silver, 0.5 wt % copper and 96.5% tin as the alloy.

The lead frame 40 can comprise any conductive material known in the art. In some embodiments, the lead frame 40 comprises Cu, Cu alloys, or Invar. Invar is a nickel-steel alloy notable for its uniquely low coefficient of thermal expansion. Invar typically has a formulation of Fe₆₄Ni₃₆.

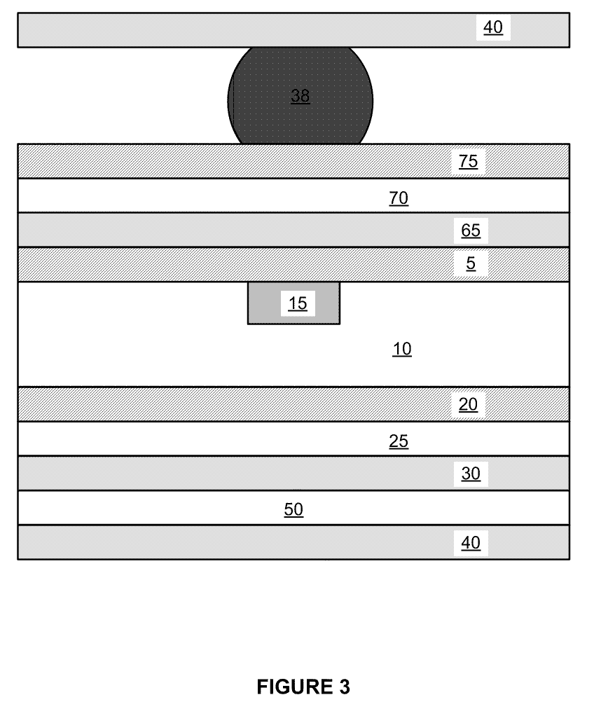

The lead frame 40 can be connected to the solder balls 35 and the solder paste 45 as known in the art. A reflow process is then performed. The reflow process causes the solder balls 35 to partially melt, flow, and form the shape of solder bumps 38 as shown in FIG. 3. The reflow process also causes the solder paste 45 to partially react with the underlying metal layers and with the lead frame 40, thereby reflowing the metal in the solder into the shape of a thin film layer 50 of solder along the entire leadframe and die backside, as shown in FIG. 3.

The resulting structure can then be encapsulated in any known molding material to make a semiconductor package, such as an epoxy molding compound, a thermoset resin, a thermoplastic material, or a potting material. The package can then be singulated using any process known in the art, including a saw singulation process or a water jet singulation process, or a laser-cut singulation method. Then, the singulated semiconductor packages may be electrically tested, taped, and reeled using any processes known in the art. The semiconductor packages can then be connected to a printed circuit board using any known connection (i.e., solder connectors) and used in any electronic device known in the art such as portable computers, disk drives, USB controllers, portable audio devices, or any other portable electronic devices.

In other embodiments, the completed semiconductor device does not contain contain a lead frame on the front side of the device. Instead, the leadframe 40 at the back side of the device is connected to the IC device 15 on the front side of the substrate 10 containing the IC device 15 using any known wire bonding process.

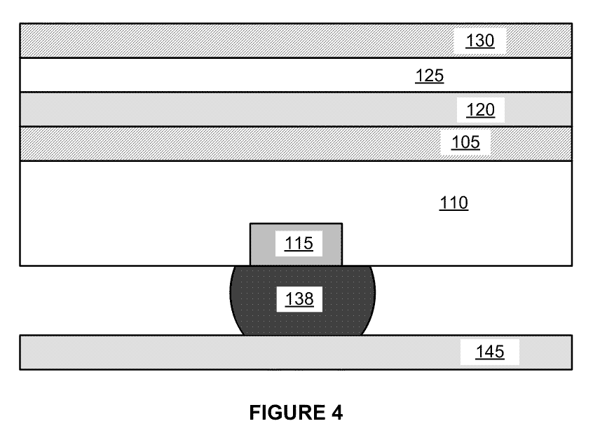

Other embodiments of the semiconductor devices and methods for making such devices are shown in FIGS. 4. In these embodiments, the TiNi soldering layer can be used in manufacturing wafer-level chip scale packages (WLCSP). In these embodiments, an IC device 115 (including the drain) is provided in a substrate front side 110 in substantially the same manner as the IC device 15 is provided in the substrate 10. The IC device 115 and the substrate 110 can be any of the IC devices or substrates described above. In some embodiments, the IC device 115 and the substrate 110 are substantially the same as the IC device 15 and the substrate 10. Then, the front side of the substrate 110 is processed as known in the art to provide an interconnect layer and a metal I/O pad for connecting a die directly to a PCB board or flipped onto solder on a lead frame. The metal I/O pad is located over a dielectric isolation layer(s) that electrically isolates the metal pad from any underlying conductive layers or transistors in the IC device. The dielectric isolation layer(s) can include BPSG (Boron Phosphorous Silicate Glass), SiO₂, SiON, or any other films known in the art that can electrically isolate the layers. Above the dielectric layer(s) a metal pad 105 can be formed on the upper surface of the resulting structure, as shown in FIG. 4, using any processing known in the art. As well, a backmetal layer can be provided as known in the art.

Next, a contact layer 120 can be formed on the gate/source pad 105. The contact layer 120 is substantially similar to—and formed in a substantially similar manner as—the contact layer 20. Then a soldering layer 125 is formed on the contact layer 120. The soldering layer 125 is substantially similar to—and formed in a substantially similar manner as—the solder layer 25. Next, an oxidation prevention (including reduction) layer 130 can be placed on the soldering layer 125. The oxidation prevention layer 130 is substantially similar to—and formed in a substantially similar manner as—the oxidation prevention (including reduction) layer 30.

Then, solder balls (not shown) can be soldered to the side of the substrate 110 containing the IC device 115. The solder ball drop process is substantially similar to—and formed in a substantially similar manner as—the solder balls 35. The die containing the solder balls can then be singulated using any process known in the art, including a saw singulation process or a water jet singulation process, or a laser-cut singulation method.

Next, a printed circuit board (PCB) 145 can be soldered to the solder balls on the front side as known in the art. A reflow process can then be performed to cause the solder balls to partially react with the underlying metal layers and the PCB and in the process, reflowing the metal in the solder into the shape of a bump 138, as shown in FIG. 4. The PCB 145 can also be connected, as known in the art, to the drain on the back side of the substrate 110. The final semiconductor device can again be used in any electronic device known in the art such as portable computers, disk drives, USB controllers, portable audio devices, or any other portable electronic devices.

The methods and semiconductor devices described above have several features. First, the devices will exhibit an improved reliability with Pb-free solder connections because of the properties of the TiNi material in the soldering layer. Second, TiNi materials—and especially Ti₄₉Ni₅₁—is more ductile and less brittle than either Ti or Ni metal layers, leading to less fracturing in the soldering layer. Third, the expensive electroless-nickel-gold (ENIG) structure containing a thick Ni layer can be potentially eliminated. When replaced with the TiNi soldering layer which can be sputtered deposited, the costs can be greatly diminished; in some instances, the costs can be diminished by about 2 orders of magnitude. Fourth, since the contact layer and the soldering layer can both be sputter deposited, the potential exists to combine the deposition of the contact layer with the deposition of the soldering layer in the same chamber, thereby enabling a single pass in the sputter deposition equipment to deposit both layers.

In some embodiments, a semiconductor device can be made by the method comprising: providing a silicon substrate containing an integrated circuit with a drain on a backside of the substrate; providing a Ti-containing contact layer contacting the drain on the backside; providing a soldering layer on the contact layer, the solder layer containing a TiNi material; providing an oxidation prevention layer on the soldering layer; and providing a Pb-free solder bump on the oxidation prevention layer.

In other embodiments, a wafer level chip scale package can be made by the method comprising: providing a silicon substrate containing an integrated circuit with gate pad or source pad located on a front side of the substrate; providing a Ti-containing contact layer on the source pad or gate pad; providing a soldering layer on the contact layer, the solder layer containing a TiNi material; providing an oxidation prevention layer on the soldering layer; providing a Pb-free solder on the oxidation prevention layer.

In yet other embodiments, a semiconductor device can be made by the method comprising, providing a silicon substrate, forming an integrated circuit in the substrate, depositing a contact layer on the substrate, depositing a TiNi soldering layer on the contact layer, depositing an oxidation prevention layer on the soldering layer, depositing and reflowing a solder bump to the soldering layer, attaching a leadframe to the drain side of the die, and reflowing the solder ball to connect to a PCB.

In addition to any previously indicated modification, numerous other variations and alternative arrangements may be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use may be made without departing from the principles and concepts set forth herein. Also, as used herein, examples are meant to be illustrative only and should not be construed to be limiting in any manner.

1. A semiconductor device, comprising:
a silicon substrate containing an integrated circuit with a drain on a backside of the substrate;
a contact layer contacting the drain on the backside, the contact layer comprising Ti, Al, or Ni;
a soldering layer on the contact layer, the solder layer containing a TiNi material;
an oxidation prevention layer on the soldering layer;
a die attach solder on the oxidation prevention layer; and
a lead frame connected to the die attach solder.

2. The device of claim 1, wherein the TiNi soldering layer contains about 0.5 to about 95.5 wt % Ni.

3. The device of claim 1, wherein the TiNi soldering layer contains about 40 to about 60 wt % Ni.

4. The device of claim 1, wherein the TiNi soldering layer contains about 50 to about 55.6 wt % Ni.

5. The device of claim 1, wherein the TiNi soldering layer contains about 51 wt % Ni.

6. The device of claim 1, wherein the thickness of the soldering layer can range from about 0.1 to about 5 μm.

7. The device of claim 1, wherein the oxidation prevention layer comprises Ag, Au, Cu, Pd, or combinations thereof.

8. A wafer level chip scale package, comprising:
a silicon substrate containing an integrated circuit connected to a gate, source or drain pad located on a front side of the substrate;
a Ti, Ni, or Al containing contact layer on the gate, source pad or gate pad;
a soldering layer on the contact layer, the solder layer containing a TiNi material;
an oxidation prevention layer on the soldering layer; and
a solder bump soldered onto the oxidation prevention layer.

9. The package of claim 8, wherein the TiNi soldering layer contains about 0.5 to about 95.5 wt % Ni.

10. The package of claim 8, wherein the TiNi soldering layer contains about 40 to about 60 wt % Ni.

11. The package of claim 8, wherein the TiNi soldering layer contains about 50 to about 55.6 wt % Ni.

12. The package of claim 8, wherein the TiNi soldering layer contains about 51 wt % Ni.

13. The package of claim 8, wherein the thickness of the soldering layer can range from about 0.1 to about 5 μm.

14. The package of claim 8, wherein the oxidation prevention layer comprises Ag, Au, Cu, Pd, or combinations thereof.

15. A soldering layer for a Pb-free solder, the soldering layer comprising a TiNi layer soldered to Pb-free solder, the TiNi layer containing about 0.5 to about 95.5 wt % Ni and a thickness of about 0.1 to about 5 μm.

16. The layer of claim 15, wherein the TiNi layer contains about 40 to about 60 wt % Ni.

17. The layer of claim 15, wherein the TiNi layer contains about 50 to about 55.6 wt % Ni.

18. The layer of claim 15, wherein the TiNi layer contains about 51 wt % Ni.

19. An electronic apparatus, comprising:
a semiconductor device connected to a printed circuit board using a Pb-free solder;
an oxidation prevention layer on the Pb-free solder; and
a soldering layer on the oxidation prevention layer, the solder layer containing a TiNi material.

20. The apparatus of claim 19, wherein the TiNi soldering layer contains about 0.5 to about 95.5 wt % Ni.

21. The apparatus of claim 19, wherein the TiNi soldering layer contains about 40 to about 60 wt % Ni.

22. The apparatus of claim 19, wherein the TiNi soldering layer contains about 50 to about 55.6 wt % Ni.

23. The apparatus of claim 19, wherein the TiNi soldering layer contains about 51 wt % Ni.

24. The apparatus of claim 19, wherein the thickness of the soldering layer can range from about 0.1 to about 5 μm.

25. The apparatus of claim 24, wherein the thickness of the soldering layer can range from about 0.2 to about 0.5 μm.

26. The device of claim 1, wherein the solder is a Pb-free solder.

27. The device of claim 1, further comprising:
a second contact layer contacting the gate pad and the source on the front side of the substrate, the contact layer comprising Ti, Al, or Ni;
a second soldering layer on the second contact layer, the solder layer containing a TiNi material;
a second oxidation prevention layer on the second soldering layer;
a second die attach solder on the second oxidation prevention layer; and
a second lead frame connected to the second die attach solder.
